(19) United States
(12) Patent Application Publication
(10) Pub. No.: US 2014/0264954 A1
(43) Pub. Date: Sep. 18, 2014

(54) PASSIVATION AND WARPAGE CORRECTION BY NITRIDE FILM FOR MOLDED WAFERS

(71) Applicant: Applied Materials, Inc., Santa Clara, CA (US)

(72) Inventors: Loke Yuen WONG, Singapore (SG); Chin Hock TOH, Singapore (SG); Aksel KITOWSKI, Singapore (SG)

(21) Appl. No.: 14/160,106

(22) Filed: Jan. 21, 2014

Related U.S. Application Data
(60) Provisional application No. 61/781,672, filed on Mar. 14, 2013.

(51) Int. Cl. H01L 25/00; H01L 23/31; H01L 21/56; H01L 25/04

(52) U.S. Cl. CPC H01L 25/50; H01L 25/04; H01L 23/31; H01L 21/565; H01L 21/561
USPC 257/787; 438/107

(57) ABSTRACT

Embodiments of the invention generally relate to molded wafers having reduced warpage, bowing, and outgassing, and methods for forming the same. The molded wafers include a support layer of silicon nitride disposed on a surface thereof to facilitate rigidity and reduced outgassing. The silicon nitride layer may be formed on the molded wafer, for example, by plasma-enhanced chemical vapor deposition or hot-wire chemical vapor deposition.

### CROSS-REFERENCE TO RELATED APPLICATIONS

This application claims benefit of U.S. Provisional Patent Application Ser. No. 61/781,672, filed Mar. 14, 2013, which is herein incorporated by reference.

### BACKGROUND OF THE INVENTION

1. Field of the Invention

Embodiments of the present invention generally relate to wafer level packaging.

2. Description of the Related Art

With trends moving towards shrinking die sizes while increasing I/O numbers and hence number of solder bumps, traditional flip-chips are facing limitations as there is insufficient real estate on the die for additional solder bumps. This limitation is mitigated by extending or “fanning-out” more space around the silicon die to take advantage of extended real estate at the peripheral space of the die, which is referred to as Fan-Out Wafer Level Packing (FO-WLP). To use existing semiconductor industry infrastructure, individual dies are molded using epoxy compound into circular 8 inch or 12 inch sized substrates, followed by typical patterning processes. Finally, these molded substrates are diced into larger sized dies and stacked onto traditional laminate substrates.

The molded wafers, however, experience significant wafer bow and warpage, resulting in robot handling issues. Additionally, molded wafers experience severe outgassing that negatively affects device performance and may contaminate process chambers.

Therefore, there is a need in the art for a molded wafer with reduced bowing, warpage, and outgassing.

### SUMMARY OF THE INVENTION

Embodiments of the invention generally relate to molded wafers having reduced warpage, bowing, and outgassing, and methods for forming the same. The molded wafers include a support layer of silicon nitride disposed on a surface thereof to facilitate rigidity and reduced outgassing. The silicon nitride layer may be formed on the molded wafer, for example, by plasma-enhanced chemical vapor deposition or hot-wire chemical vapor deposition.

In one embodiment, a molded substrate comprises a plurality of dies embedded in a molding compound comprising an epoxy. Each die has an exposed surface. The molded substrate also includes a support layer comprising silicon nitride coupled to a surface of the molding compound.

In another embodiment, a method of forming a molded substrate comprises positioning a plurality of die on a carrier substrate, applying a molding compound to the carrier substrate, compressing and heating the molding compound, removing the carrier substrate, and applying a support layer to the molding compound.

In another embodiment, a method of forming a molded substrate comprises positioning a plurality of die on a carrier substrate, applying a molding compound to the carrier substrate, removing the carrier substrate, and applying a support layer to the molding compound.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional view of a chemical vapor deposition chamber used to practice embodiments of the invention.

FIG. 2 illustrates a flow diagram of operations for processing molded substrates, according to one embodiment of the invention.

FIGS. 3A-3G illustrate a molded substrate during processing, according to one embodiment of the invention.

FIGS. 4A-4C illustrate a substrate during processing, according to another embodiment of the invention.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the invention generally relate to molded wafers having reduced warpage, bowing, and outgassing, and methods for forming the same. The molded wafers include a support layer of silicon nitride disposed on a surface thereof to facilitate rigidity and reduced outgassing. The silicon nitride layer may be formed on the molded wafer, for example, by plasma-enhanced chemical vapor deposition or hot-wire chemical vapor deposition.

FIG. 1 is a schematic cross-sectional view of a chemical vapor deposition system 100 used to practice embodiments of the invention. The chemical vapor deposition system 100 is available from Applied Materials, Inc., of Santa Clara, Calif. However, it is contemplated that other chambers, including those from other manufacturers may be used to practice embodiments of the invention. The chemical vapor deposition system 100 may be utilized to deposit a support layer, such as a silicon nitride layer of the present invention.

The system 100 generally includes a chemical vapor deposition chamber 103 coupled to a precursor supply 152. The chemical vapor deposition chamber 103 has sidewalls 106, a bottom 108, and a lid assembly 110 that define a processing volume or region 112 inside the chemical vapor deposition chamber 103. The processing region 112 is typically accessed through a port (not shown) in the sidewalls 106 that facilitate movement of a substrate 140 into and out of the chemical vapor deposition chamber 103. The sidewalls 106 and bottom 108 are typically fabricated from aluminum, stainless steel, or other materials compatible with processing. The sidewalls 106 support a lid assembly 110 that contains a pumping plenum 114 that couples the processing region 112 to an exhaust system that includes various pumping components (not shown). The sidewalls 106, bottom 108, and lid assembly 110 define the chamber body 102.

A gas inlet conduit or pipe 142 extends into an entry port or inlet 180 in a central lid region of the chamber body 102 and is connected to sources of various gases. A precursor supply 152 contains the precursors that are used during deposition. The precursors may be gases or liquids. The particular precursors that are used depend upon the materials that are to be deposited onto the substrate, and in one example, may include silane in addition to nitrogen and/or ammonia. The process gases flow through the inlet pipe 142 into the inlet 180 and then into the chamber 103. An electronically operated valve and flow control mechanism 154 controls the flow of gases from the gas supply into the inlet 180.

A second gas supply system is also connected to the chamber through the inlet pipe 142. The second gas supply system supplies gas that is used to clean, e.g., remove deposited material, the inside of the chamber after one or more chemical vapor deposition processes have been performed in the chamber. In some situations, the first and second gas supplies can be combined.

The second gas supply system includes a source 164 of a cleaning gas (or liquid), such as nitrogen trifluoride or sulfur hexafluoride, a remote plasma source 166 which is located outside and at a distance from the chemical vapor deposition chamber, an electronically operated valve and flow control mechanism 170, and a conduit or pipe 177 connecting the remote plasma source to the chemical vapor deposition chamber 103. Such a configuration allows interior surfaces of the chamber to be cleaned using a remote plasma source.

The second gas supply system also includes one or more sources 172 of one or more additional gases (or liquids) such as oxygen or a carrier gas. The additional gases are connected to the remote plasma source 166 through another valve and flow control mechanism 173. The carrier gas aids in the transport of the reactive species generated in the remote plasma source to the deposition chamber and can be any nonreactive gas that is compatible with the particular cleaning process with which it is being used. For example, the carrier gas may be argon, nitrogen, or helium. The carrier gas also may assist in the cleaning process or help initiate and/or stabilize the plasma in the chemical vapor deposition chamber.

Optionally, a flow restrictor 176 is provided in the pipe 177. The flow restrictor 176 can be placed anywhere in the path between the remote plasma source 166 and the deposition chamber 103. The flow restrictor 176 allows a pressure differential to be provided between the remote plasma source 166 and the deposition chamber 103. The flow restrictor 176 may also act as a mixer for the gas and plasma mixture as it exits the remote plasma source 166 and enters the deposition chamber 103.

The valve and flow control mechanism 170 delivers gas from the source 164 into the remote plasma source 166 at a user-selected flow rate. The remote plasma source 166 may be an RF plasma source, such as an inductively coupled remote plasma source. The remote plasma source 166 activates the gas or liquid from the source 164 to form reactive species which are then flowed through the conduit 177 and the inlet pipe 142 into the deposition chamber through the inlet 180. The inlet 180 is, therefore, used to deliver the reactive species into the interior region of the chemical vapor deposition chamber 103.

The lid assembly 110 provides an upper boundary to the processing region 112. The lid assembly 110 includes a central lid region 105 in which the inlet 180 is defined. The lid assembly 110 typically can be removed or opened to service the chemical vapor deposition chamber 103. In one embodiment, the lid assembly 110 is fabricated from aluminum (Al). The lid assembly 110 includes a pumping plenum 114 formed therein coupled to an external pumping system (not shown). The pumping plenum 114 is utilized to channel gases and processing by-products uniformly from the processing region 112 and out of the chemical vapor deposition chamber 103.

The gas distribution assembly 118 is coupled to an interior side 120 of the lid assembly 110. The gas distribution assembly 118 includes a perforated area 116 in a gas distribution plate 158 through which gases, including reactive species generated by the remote plasma source and processing gases for chemical vapor deposition, are delivered to the processing region 112. The perforated area 116 of the gas distribution plate 158 is configured to provide uniform distribution of gases passing through the gas distribution assembly 118 into the process volume 112.

The gas distribution plate 158 is typically fabricated from stainless steel, aluminum (Al), anodized aluminum, nickel (Ni) or another RF conductive material. The gas distribution plate 158 is configured with a thickness that maintains sufficient flatness and uniformity so as to not adversely affect substrate processing. In one embodiment the gas distribution plate 158 has a thickness between about 1.0 inch and about 2.0 inches.

In addition to inlet 180, the chamber body 102 may optionally include a second inlet 182 that provides reactive species from a remote plasma source. The remote plasma source may be the same remote plasma source 166 that provides reactive species to the processing region through the inlet 180 via the gas distribution assembly 118. The second inlet 182 is configured to provide reactive species from the remote plasma source into the processing region 112 of the chamber 103 while bypassing the gas distribution assembly 118. In other words, the reactive species provided by the second inlet 182 do not pass through the perforated gas distribution plate 158 of the gas distribution assembly 118. The second inlet 182 may be located in a sidewall 106 of the chamber body 102 below the gas distribution assembly 118, such as between the gas distribution plate 158 and the substrate support 124. A gas line 184 from the remote plasma source to the second inlet 182 delivers reactive species from the remote plasma source to the processing region 112 of the chamber 103 through the second inlet 182. In such an embodiment, a diverter 179 is provided in the gas line 177 from the remote plasma source. The diverter 179 allows a first portion of the reactive species from the remote plasma source 166 to be directed to the first inlet 180 of the chamber 103 via line 142 between the diverter 179 and the chamber 103 and a second portion of the reactive species from the remote plasma source to be directed to the second inlet 182 of the chamber via line 184 between the diverter 179 and the chamber 103.

A temperature controlled substrate support assembly 138 is centrally disposed within the chamber 103. The support assembly 138 supports a substrate 140 during processing. In one embodiment, the substrate support assembly 138 comprises a substrate support 124 having an aluminum or aluminum nitride body that encapsulates at least one embedded heater 132. The heater 132, such as a resistive element, disposed in the support assembly 138, is coupled to an optional power source 174 and controllably heats the support assembly 138 and the substrate 140 positioned thereon to a predetermined temperature.

Generally, the support assembly 138 has a substrate support 124 comprising a lower side 126 and an upper side 134. The upper side 134 supports the substrate 140. The lower side 126 has a stem 142 coupled thereto. The stem 142 couples the support assembly 138 to a lift system (not shown) that moves the support assembly 138 between an elevated processing position (as shown) and a lowered position that facilitates substrate transfer to and from the chemical vapor deposition chamber 103. The stem 142 additionally provides a conduit for electrical and thermocouple leads between the support assembly 138 and other components of the system 100.

A bellows 146 is coupled between support assembly 138 (or the stem 142) and the bottom 108 of the chemical vapor deposition chamber 103. The bellows 146 provides a vacuum seal between the processing region 112 and the atmosphere outside the chemical vapor deposition chamber 103 while facilitating vertical movement of the support assembly 138.

The support assembly 138 generally is grounded such that RF power supplied by a power source 122 to the gas distribution assembly 118 positioned between the lid assembly 110 and substrate support assembly 138 (or other electrode positioned within or near the lid assembly of the chamber) may excite gases present in the processing region 112 between the support assembly 138 and the gas distribution assembly 118. The support assembly 138 additionally supports a circumscribing shadow frame 148. Generally, the shadow frame 148 prevents deposition at the edge of the substrate 140 and support assembly 138 so that the substrate does not adhere to the support assembly 138. The support assembly 138 has a plurality of holes 128 disposed therethrough that accept a plurality of lift pins 150.

FIG. 2 illustrates a flow diagram 200 of operations for processing molded substrates with silicon nitride layers thereon, according to one embodiment of the invention. FIGS. 3A-3G illustrate a molded substrate during processing, according to one embodiment of the invention. To facilitate explanation of embodiments of the invention, FIGS. 2 and 3A-3G will be explained in conjunction.

Flow diagram 200 begins at operation 202, in which a multiple die 320 (e.g., integrated circuits), are coupled to a carrier substrate 322 using an adhesive 324, as shown in FIG. 3A. The carrier substrate may be, for example, a metal or glass sheet having sufficient strength and rigidity to support the die 320 thereon. In one embodiment, the carrier substrate 322 may be quartz or aluminum. The adhesive 324 is an adhesive material, such as thermal release tape or another adhesive material that does not adversely react with the carrier substrate 322 or the die 320.

In operation 204, after placement of the die 320, a molding compound 326 is applied over and around the die 320, as shown in FIG. 3B. The molding compound is an epoxy material, such as Novalac epoxy or bis-phenol A based epoxy. In operation 206, sufficient heat and pressure are applied to the carrier substrate 322 and the molding compound 326 to form and set the molding compound 326, thus forming a molded substrate 328, as shown in FIG. 3C. It is to be understood that the amount of pressure and the temperature are dependent upon the specific molding compound 326 that is selected. A mechanical press and heater (not shown) may be used to facilitate setting of the molding compound. It is also contemplated that a molding compound which does not require heat and/or pressure may be utilized. In one embodiment, the molding compound 326 may have a thickness of about 400 micrometers to about 700 micrometers.

In operation 208, the carrier substrate 322 and the adhesive 324 are removed from the molded substrate 328, as shown in FIG. 3D. The carrier substrate 322 and the adhesive 324 may be removed, for example, by mechanical separation, or by chemically removing or inactivating the adhesive 324. Desirably, the removal process in operation 208 facilitates reuse of the carrier substrate 322 and does significantly damage the dies 320 or the molding compound 326.

In operation 210, a support layer 300 is applied to the molded substrate 326, as shown in FIG. 3E. The support layer 330 is applied to a side of the molded substrate 328 opposite the exposed surface 332 of the dies 320. Thus, the die 320 remain partially exposed to facilitate connections therewith, for example, during packing. The support layer 330 may deposited by chemical vapor deposition, using, for example, the chemical vapor deposition system 100 shown in FIG. 1, or a Produce Avila™ system available from Applied Materials of Santa Clara, Calif. The presence of the support layer 330 facilitates increased structural rigidity of the molded substrate 328. The increased structural rigidity of the molded substrate 328 reduces bowing and warpage of the molded substrate 328. The more rigid molded substrate 328 can be more easily handled, for example, by robots, due to the increased structural rigidity.

In addition to increasing the structural rigidity of the molded substrate 328, the support layer 330 also reduces outgassing of the molded substrate 328. Often, the epoxy material selected for the molding compound 326 outgases, especially moisture, which negatively affects device performance, as well as any processing equipment containing the outgassing material at the time of outgassing.

In one example, the support layer 330 is a silicon nitride layer having a thickness within a range of about 5000 angstroms to about 10000 angstroms. The silicon nitride layer applies compressive or tensile stress to the molded substrate 328, which compensates for natural bow or warpage of the molded substrate 328, thus assisting the molded substrate 328 in maintaining a more planar shape or orientation. In addition, the silicon nitride layer possesses excellent hermetic and barrier properties that impede the outgassing of moisture and other contaminants during processing.

The increased structural rigidity imparted by the support layer 330 is beneficial when optionally transferring the molded substrate 328 after formation of the support layer 330. In one embodiment, after formation of the support layer 330, the molded substrate 328 is transferred to one or more processing chambers for additional processing, including patterning, etching, or deposition processes. For example, the molded wafer may be optionally patterned, and interconnects may be formed in a surface of the molded wafer 328 adjacent to the dies 320. Subsequent to the optional additional processing, flow diagram 200 proceeds to operation 212.

In operation 212, the molded substrate 328 having the support layer 330 thereon is cut or diced to separate the individual die 320 to form molded dies 334, as shown in FIG. 3F. As illustrated in FIG. 3F, a portion of the molding compound 326 and the support layer 330 remains coupled to each or the die 320. Although the support layer 330 is generally no longer need for support purposes after separation of the molded substrate 328 into individual die, the continued presence of the support layer 330 facilitates a reduction in outgassing.

In step 214, the molded dies 334 are disposed on a laminate substrate 336 for packaging, as shown in FIG. 3G. The molded dies 334 are coupled to the laminate substrate 336 using, for example, solder balls 338. The laminate substrate may include, for example, Bismaleimide-Triazine or a glass epoxy such as FR4.

FIGS. 2 and 3A-3G illustrate one embodiment of the invention; however, other embodiments are also contemplated. In another embodiment, it is contemplated that operation 210 may precede operation 208.

FIGS. 4A-4C illustrate a substrate 450 during processing, according to another embodiment of the invention. As shown in FIG. 4A, the substrate 450 is for example a silicon wafer. The substrate 450 includes an electrically conductive vias 452 disposed therein, and a dies 454 disposed on the substrate in electrical communication with the vias 452. A molding compound 456, which is similar to the molding compound 326, is disposed over the dies 454. The molding compound 456 facilitates encapsulation of the dies 454.

As shown in FIG. 4B, a support layer 458 is disposed over the molding compound 456. The support layer 458 is similar to the support layer 330, and may include, for example, silicon nitride. The support layer 458 reduces outgassing of the molding compound 456, and provides structural rigidity to the substrate 450, particularly after thinning as shown in FIG. 4C.

FIG. 4C illustrates the substrate 450 after the substrate 450 has been thinned to facilitate device packing. The reduced thickness of the substrate 450 allows the substrate 450 to be packaged in a small package. However, after thinning, the substrate 450 has a tendency to bow or warp. The presence of the support layer 458 allows the substrate 450 to be thinned and still maintain a substantially planar shape. Thus, as illustrated, support layers, such as the support layers 458 and 330 facilitate increased rigidity of substrates, particularly substrates including molding compounds. In one example, the substrate 450 and the molding compound may have a combined thickness of about 700 micrometers to about 1400 micrometers.

Although embodiments herein are described with respect to a silicon nitride support layer, it is contemplated that other materials may alternatively be utilized. For example, it is contemplated that the support layer may include one or more metals, including tungsten and/or titanium.

Benefits of the invention include decreased bowing, warpage, and outgassing of molded substrates. The increased structural rigidity of the molded substrates facilitates handling of the molded substrates. In one example, subsequent to application of a support layer, the molded substrate may then be transferred to one or more process chambers, such as a chemical vapor deposition chamber or a physical vapor deposition chamber, prior to separating the molded substrate into individual die. The increased structural rigidity imparted by the support layer facilitates substrate handling. Therefore, specialized tools that may be relatively expensive, would not be necessary to effect transfer of the molded substrate, and damage of the molded substrate is reduced. Additionally, the reduced outgassing of the molded substrates allows for shorter times in degassing tools, thus increasing throughput.

While the foregoing is directed to embodiments of the present invention, other and further embodiments of the invention may be devised without departing from the basic scope thereof, and the scope thereof is determined by the claims that follow.

We claim:

1. A molded substrate, comprising:
a plurality of dies embedded in a molding compound comprising an epoxy, each die having an exposed surface; and
a support layer coupled to a surface of the molding compound.

2. The molded substrate of claim 1, wherein the support layer is silicon nitride.

3. The molded substrate of claim 1, wherein the support layer comprises titanium.

4. The molded substrate of claim 3, wherein the support layer further comprises tungsten.

5. The molded substrate of claim 1, wherein the support layer comprises a metal.

6. The molded substrate of claim 1, wherein the molding compound has a thickness within a range of about 400 micrometers to about 700 micrometers.

7. A method of forming a molded substrate, comprising:
positioning a plurality of die on a carrier substrate;
applying a molding compound to the carrier substrate;
compressing and heating the molding compound;
removing the carrier substrate; and
applying a support layer to the molding compound.

8. The method of claim 7, further comprising separating each die of the plurality of die.

9. The method of claim 7, wherein the support layer is deposited by plasma-enhanced chemical vapor deposition.

10. The method of claim 7, wherein the support layer is deposited by hot wire chemical vapor deposition.

11. The method of claim 7, wherein the support layer includes silicon nitride.

12. The method of claim 7, wherein the carrier substrate comprises aluminum.

13. The method of claim 7, wherein the carrier substrate comprises quartz.

14. The method of claim 7, wherein the plurality of die are adhered to the carrier substrate using an adhesive.

15. The method of claim 7, wherein the support layer has a thickness within a range of about 5,000 angstroms to about 10,000 angstroms.

16. The method of claim 7, wherein the support layer comprises titanium.

17. The method of claim 16, wherein the support layer further comprises tungsten.

18. The method of claim 7, wherein the carrier substrate is removed prior to applying the support layer.

19. The method of claim 7, wherein the carrier substrate is removed subsequent to removing the carrier substrate.

20. A method of forming a molded substrate, comprising:
positioning a plurality of die on a carrier substrate;
applying a molding compound to the carrier substrate;
removing the carrier substrate; and
applying a support layer to the molding compound.
